(19) United States
(12) Patent Application Publication
(10) Pub. No.: US 2022/0213598 A1
(43) Pub. Date: Jul. 7, 2022

(54) APPARATUS AND METHOD FOR IN-SITU MICROWAVE ANNEAL ENHANCED ATOMIC LAYER DEPOSITION

(71) Applicant: Oregon State University, Corvallis, OR (US)

(72) Inventor: John F. Conley, Jr., Corvallis, OR (US)

(73) Assignee: Oregon State University, Corvallis, OR (US)

(21) Appl. No.: 17/609,745

(22) PCT Filed: May 19, 2020
(86) PCT No.: PCT/US2020/033657

§ 371 Date: Nov. 8, 2021

Related U.S. Application Data
(60) Provisional application No. 62/851,016, filed on May 21, 2019.

(51) Int. Cl. C23C 16/455; C23C 16/56

(52) U.S. Cl. CPC C23C 16/45536; C23C 16/56; C23C 16/45544

(57) ABSTRACT

Microwave annealing (MWA) is used in-situ within an atomic layer deposition (ALD) chamber so that deposited material can be directly exposed to microwave heating without removing the material from the ALD chamber. A microwave source is integrated in-situ within an ALD chamber to provide direct microwave interaction with defects and impurities in layer(s) deposited on a substrate. As such, the need to remove the substrate and film between cycles for annealing is eliminated. In-situ MWAs allow for improved ALD film properties at lower temperature, without negatively impacting throughput.

### CLAIM FOR PRIORITY

This application claims priority to U.S. Provisional Patent Application No. 62/851,016, filed on May 21, 2019, titled “APPARATUS AND METHOD FOR IN-SITU MICROWAVE ANNEAL ENHANCED ATOMIC LAYER DEPOSITION,” and which is incorporated by reference in its entirety.

### BACKGROUND

Atomic layer deposition (ALD) is a layer by layer chemical vapor deposition (CVD) technique based on alternating purge-separated self-limiting surface reactions. ALD offers inherent atomic scale controlled growth of relatively high quality conformal thin films at relatively low temperatures. While low deposition temperature is desirable, as a result, ALD film stoichiometry often suffers due to the incorporation residual impurities from unreacted ligands, which in turn may lead to sub-optimal physical, optical, and electrical properties. High temperature post deposition annealing (PDA) is often required to eliminate impurities, densify the film, and improve various properties. The PDA temperatures required, however, can exceed the maximum temperature limitations of the substrate or previously formed electronics. For example, if depositions are performed in the back end of line, diffusion of existing metal lines can be problematic if anneal temperatures exceed approximately 400° C.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-section of an Atomic Layer Deposition (ALD) chamber with in-situ microwave (MW) source, in accordance with some embodiments.

FIG. 2 illustrates a cross-section of an ALD chamber with multiple MW sources, in accordance with some embodiments.

FIGS. 3A-B illustrate cross-sections of ALD chambers with multiple chambers and/or multiple MW sources, in accordance with some embodiments.

FIG. 4 illustrates an ALD flow with repeated MW annealing (MWA) steps to purify film over substrate, in accordance with some embodiments.

FIGS. 5-10 illustrate ALD flows with different MWA sequences in the ALD process, in accordance with some embodiments.

FIG. 11 illustrates a computer system which is operable to perform, all or in-part, any one of the schemes described with reference to FIGS. 1-10, in accordance with some embodiments.

### DETAILED DESCRIPTION

Atomic layer deposition (ALD) is based on alternating purge-separated self-limiting surface reactions, resulting in well-known benefits such as atomic scale controlled deposition of relatively high quality conformal thin films at low temperatures. While low deposition temperature is desirable, ALD film stoichiometry often suffers due to the incorporation of residual impurities from unreacted ligands, which in turn may lead to sub-optimal physical, optical, and electrical properties. A number of approaches may be used to reduce impurities, increase density, improve properties, and achieve desired morphology.

The most common approach is post-deposition annealing (PDA) at elevated temperatures. However, the PDA temperatures can often exceed the maximum thermal budget for sensitive substrates or devices. Incorporating brief lower temperature in-situ rapid thermal anneals (RTAs) at intervals of every n ALD cycles (where n is a number) can improve film properties (e.g., increased film density and dielectric constant; reduced electrical defects and residual contamination) beyond that which can be reached by even much higher temperature post deposition anneals. Unfortunately, modulated temperature ALD (also referred to as dep-anneal-dep anneal (DADA)) may be impractical for manufacturing due to the long post RTA cool down times required to come back to the ALD process temperature.

Other related methods include in-situ flash annealing which uses shorter heating pulses to dissociate reactants and is more akin to pulsed chemical vapor deposition (CVD), in-situ photo-assisted ALD, in which UV light of various wavelengths is used to supply energy to surface reactions so as to reduce deposition temperature and tailor film properties, and in-situ Ar-plasma anneal. However, these related methods come with drawbacks. For example, in in-situ photo-assisted ALD, UV exposure can cause damage and charge trapping in dielectric films.

Microwaves allow for rapid volumetric heating as well as lower temperatures as compared to conventional annealing due to non-thermal effects. In some embodiments, microwave annealing (MWA) is used in-situ within an ALD chamber so that the deposited material can be directly exposed to microwave heating without removing the material from the ALD chamber.

While various embodiments are described with reference to a single ALD chamber with a single MWA source, a single ALD device may have multiple sub-chambers in fluid communication with each other such that a single substrate can be moved between or through different processes steps without unnecessary breaking of vacuum or purging of the entire volume of the device. In some embodiments, the MWA source may be in one such area of the ALD device while deposition may occur in an adjacent portion of the same device. In some embodiments, a single ALD chamber may have multiple MWA sources.

Microwave heating works through ohmic conduction loss and dielectric polarization loss and should not include a microwave-generated plasma. In some embodiments, voltage and pressure can be controlled to minimize or eliminate the generation of a plasma within an ALD chamber. For example, at very low pressures or near atmospheric pressures, the voltage for igniting and sustaining a plasma becomes very high.

The mechanism of MWA of various embodiments is attributed to thermal effects and also direct interaction of microwave radiation with dipoles in the film as well as non-thermal effects (not directly related to thermal heating). Properties that may be improved using MWA in-situ in an ALD chamber include optical properties, electrical properties, and other properties that depend on material purity, density, and defect density. Other technical effects will be evident from the various figures and embodiments.

Microwaves efficiently couple with a variety of polar materials, such as ZnO. Absorption of microwave power by Si is doping and temperature dependent. For non-polar materials such as Al₂O₃ or SiO₂ that do not absorb microwave energy well, materials such as SiC, which is an excellent absorbers of microwave radiation, or Si can be used as a susceptor to transfer heat to materials that are microwave transparent.

Microwaves can also induce dipoles and couple with defects and impurities. As such, vacancies, interstitials, and residual impurities such as water and carbon contamination may also couple with microwave radiation via induced dipoles, even in an otherwise microwave transparent material, to be selectively heated and reduced or eliminated. As these defects are often associated with electrical traps that degrade device performance, reducing these defects should improve performance. Water and alcohols in particular are polarizable and may also be responsive to microwave heating when on the surface of a wafer, of particular use for ALD.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Throughout the specification, and in the claims, the term “connected” means a direct connection, such as electrical, mechanical, or magnetic connection between the things that are connected, without any intermediary devices.

The term ‘in-situ,’ here generally refers to a microwave annealing source within an ALD chamber or sub-chamber so that the deposited material can be directly exposed to microwave heating without removing the material from the chamber or sub-chamber.

The term “coupled” means a direct or indirect connection, such as a direct electrical, mechanical, microwave, or magnetic connection between the things that are connected or an indirect connection, through one or more passive or active intermediary devices.

The term “adjacent” here generally refers to a position of a thing being next to (e.g., immediately next to or close to with one or more things between them) or adjoining another thing (e.g., abutting it).

The term “circuit” or “module” may refer to one or more passive and/or active components that are arranged to cooperate with one another to provide a desired function.

The term “signal” may refer to at least one current signal, voltage signal, magnetic signal, microwave signal, electromagnetic signal, or data/clock signal. The meaning of “a,” “an,” and “the” include plural references. The meaning of “in” includes “in” and “on.”

The terms “substantially,” “close,” “approximately,” “near,” and “about,” generally refer to being within +/−10% of a target value.

Unless otherwise specified, the use of the ordinal adjectives “first,” “second,” and “third,” etc., to describe a common object, merely indicate that different instances of like objects are being referred to and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The terms “left.” “right,” “front,” “back,” “top,” “bottom,” “under,” and the like in the description and in the claims, if any, are used for descriptive purposes and not necessarily for describing permanent relative positions.

It is pointed out that those elements of the figures having the same reference numbers (or names) as the elements of any other figure can operate or function in any manner similar to that described but are not limited to such.

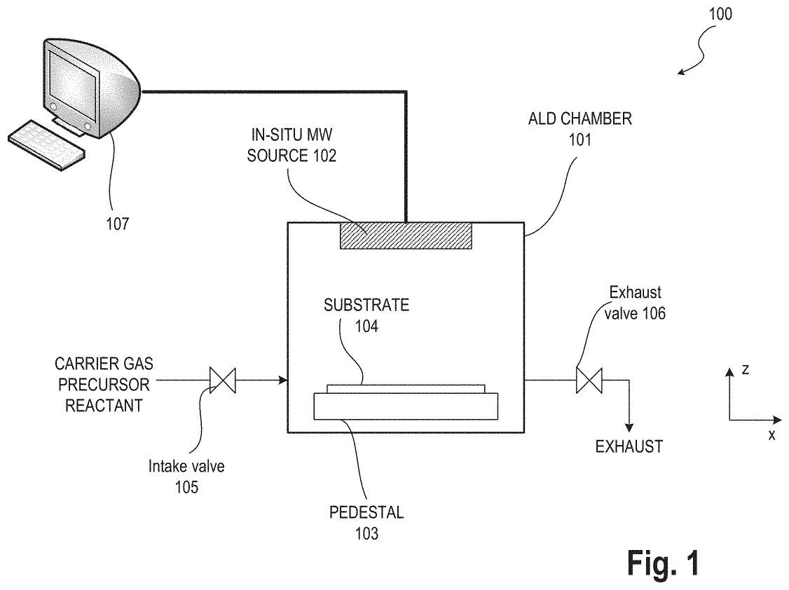

FIG. 1 illustrates apparatus 100 showing cross-section of an ALD chamber with in-situ microwave source (MW source), in accordance with some embodiments. In some embodiments, apparatus 100 includes ALD chamber 101, in-situ MW source 102, pedestal 103 which carries a target material or substrate 104 (e.g., Si substrate), control and line 105 for carrier gas precursor reactant, control and line 106, and computer terminal 107. Prior to ALD, substrate 104 undergoes appropriate preparation such as a HF bath to provide an H-terminated silicon surface, cleaning, UV (ultraviolet) Ozone, etc.

In some embodiments, MW source 102 is integrated in-situ within ALD chamber 101 to provide direct microwave interaction with defects and impurities in layer(s) deposited on substrate 104. As such, the need to remove substrate 104 and film formed on it between cycles for annealing is eliminated. In-situ MWAs allow for improved ALD film properties at lower temperature, without negatively impacting throughput. Apparatus 100 reduces processing time as compared to similar technology available in the art.

In some embodiments, MW source 102 provides power in a range from 50 Watt (W) to 5000 W at a frequency ranging from 915 MHz to 24.125 GHz. The power and frequency of MW source 102 is adjustable or programmable by a computer terminal 107. Computer terminal 107 can be connected to ALD chamber 101 (or ALD machine) by wireless or wired means. In some embodiments, MW source 102 is physically adjustable within ALD chamber 101. For example, MW source 102 can be moved and locked in position along a z-direction and/or x-y direction to adjust direction of microwaves towards substrate 104. As such, MW source 102 directs microwave on a surface of substrate 104. In some embodiments, the physical adjustment of MW source 102 is made manually with clamps and screws, for example. In some embodiments, the physical adjustment of MW source 102 is performed by electrical/mechanical means controlled by computer terminal 107. In some embodiments, MW source 102 can be programmable to adjust a frequency and/or power of MW source 102 to control the microwave annealing.

In ALD, precursor vapors are injected into chamber 101 via control and line 105. The control and line 105 includes valve (intake valve) to close or open passage of to be deposited material through line 105. Precursor vapors (e.g., metal nitrate precursor, Hf(NO₃)₄, metal halide precursor, such as [M⁺]Cl₄, HfCl₄, Al(CH₃)₃ and H₂O, and bis(tertbutylamino)silane or Si₂C₁₆ and NH₃) are injected in alternating sequences. For example, precursor vapors are injected followed by purging gas, injecting reactant, and purging gas. Gas is purged via control and line 106. The control and line 106 includes a valve (outtake valve) to close or open passage of exhaust material through line 106. The precursor adsorbs onto substrate 104. While one intake valve and one outtake valve are shown, any number of intake valves and outtake valves may be coupled to ALD chamber 101. The precursor vapors (or simply precursor) reacts with a reactant to form a desired film on substrate 104. Precursors readily adsorb at bonding sites on the deposited surface in a self-limiting mode.

The process of ALD comprises placing a wafer (e.g., substrate 104) on a pedestal 104. In some embodiments, position of pedestal 104 is adjustable to align it with MW source 102 so that microwaves directly hit the surface substrate 104. The adjustment of pedestal 104 can be manual or by electrical/mechanical means via computer terminal 107. In some embodiments, the wafer is placed on a substrate heater in a vacuum chamber. The temperature of substrate 104 is prepared for the adsorption of the precursor. This temperature can range between room temperature to 500° C., for example, depending on the process. The temperate is set for optimal absorption and to prevent deposition on the walls of chamber 101 and/or damage to substrate 104. To prevent condensation of the precursor, the walls of chamber 101 have the same temperature (e.g., between 50° C. and 200° C.) as the precursor vapor. In some embodiments, the wall of chamber 101 are cold wall system where the walls are not actively heated.

Chamber 101 is then purged to remove unwanted gases inside chamber 101, and the temperature is stabilized. For example, Ar gas (or N₂, or He gas) is supplied via control and line 105 to stabilize chamber temperature and pressure. After chamber 101 is purged, first precursor dose valve 105 is opened and chamber 101 is provided with the first precursor. This first precursor may stick to the surfaces of substrate 104. Followed by the first precursor dose, a first purge is performed. In the first purge, dose valve 105 is closed and precursor lines are purged with, for example Ar, while the gas precursor is pumped away via exhaust valve 106. This leaves only the precursor that reacts on substrate 104.

Thereafter, second precursor valve is open. The second precursor valve can be the same intake valve 105 that supplies the second precursor or can be a separate intake valve (not shown). The second precursor reacts with the first precursor to form a film over substrate 104. After supplying the second precursor, the second precursor valve is closed and the second precursor lines are purged with Ar (or N₂ or He) while gas precursor is pumped away via valve 106. This leaves the second precursor that reacts on the surface of substrate 104. The process of flooding chamber 101 with precursors and purging the precursor via outtake valve(s) 106 is repeated a number of times until a desired thickness of a film is formed on substrate 104.

Material deposited per ALD cycle is typically a fraction of a monolayer (e.g., approximately ⅓) or as little as about 0.1 nm/cycle. However, ALD depositions can range from 0.01 nm/cycle or even lower and up to perhaps 1 monolayer per cycle (e.g., approximately 0.3 nm to 0.5 nm) for true ALD, and up to many monolayers for catalytically enhanced ALD processes. In some examples, application thickness is from 0.5 nm for the thinnest up to about 200 nm for conventional temporal ALD into the range of a few microns for optimized high speed spatial ALD processes.

In-situ microwave annealing enhanced ALD of various embodiments produce films better than standard ALD, but as good as those from RTA enhanced, flash enhanced, or UV enhanced ALD, but with reduced thermal budget and reduced impact to throughput. Due to direct microwave interaction with defects and impurities, wafer (or substrate 104) cool down time may be reduced, overcoming a significant disadvantage of in-situ RTA-enhanced ALD and without the potential detrimental effects of UV exposure. Utilized every n cycles, MWA at 915 MHz to 5.8 GHz or higher, for a duration ranging from a second to several minutes to tens of minutes, at power levels of 50-5000 W, MWAs allow unreacted ligands to diffuse out of the growing film before they effectively become trapped by the overlying deposited material. This yields films of increased purity (such as reduced H₂O and carbon), increased density, and improved electronic, optical, and diffusion barrier properties. In-situ MWA is also applied to spatial ALD for higher throughput, in accordance with some embodiments.

In accordance with some embodiments, in-situ MWA a may be done after every deposition cycle, or after several cycles up to n cycles. This may be optimized depending on the impurities and defects and material(s) involved and ease of diffusion in the material. In some embodiments, n ranges from 1 to 50 deposition cycles. In other embodiments, n ranges from 1 to 4 cycles. In yet other embodiments, n is 1 and a MWA will be performed after every deposition cycle.

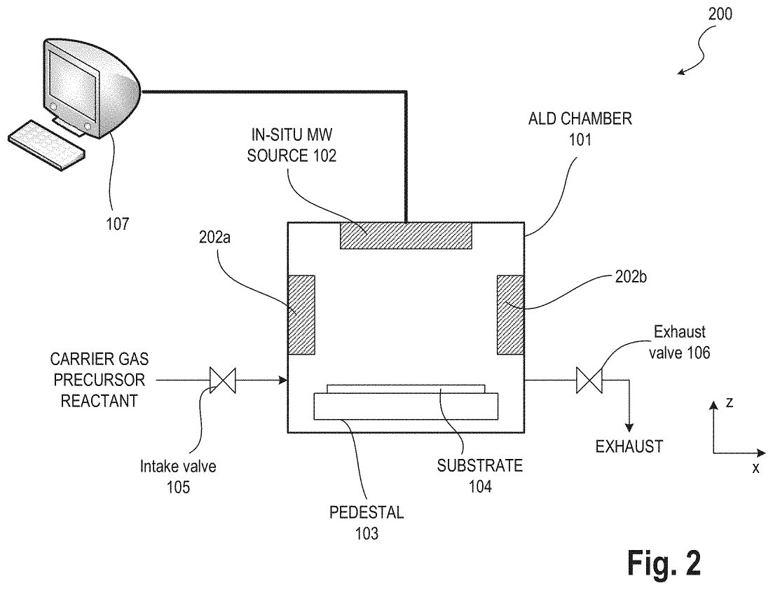

FIG. 2 illustrates apparatus 200 of a cross-section of an ALD chamber with multiple MW sources, in accordance with some embodiments. Compared to apparatus 200 here multiple MW sources 102, 202a, and 202b are provided in chamber 101. In some embodiments, each MW source can be independently controlled. For example, the frequency and power of MW sources 102, 202a, and 202b are independently controllable by computer terminal 107.

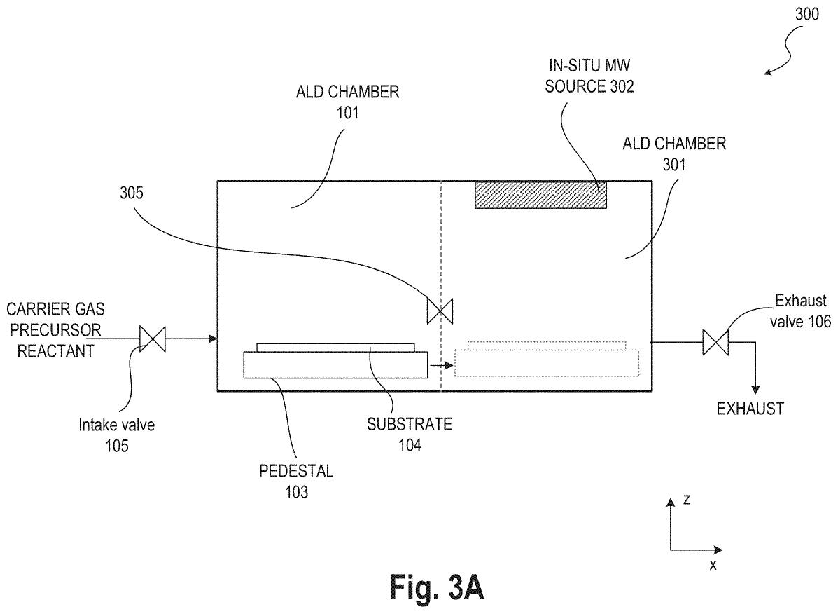

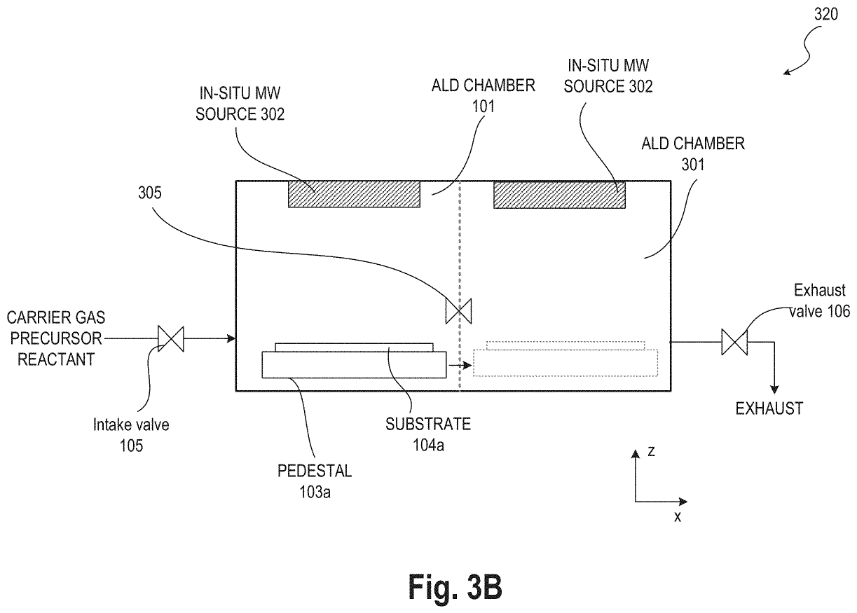

FIGS. 3A-B illustrate cross-sections 300 and 320, respectively, of ALD chambers with multiple chambers and/or multiple MW sources, in accordance with some embodiments. In some embodiments, multiple chambers (or sub-chambers) are coupled with one another in a single ALD apparatus. In this example, two sub-chambers 101 and 301 are shown. However, any number of sub-chambers may be housed in a single ALD apparatus. Sub-chambers 101 and 301 are in fluid communication (e.g., via control and line 305) with each other such that a single substrate 104 can be moved between or through different process steps without breaking vacuum of the entire volume of the device. In some embodiments, MW source 302 may be in one such area of the ALD device (e.g., chamber 301) while deposition may occur in an adjacent portion (e.g., chamber 101) of the same ALD apparatus. In some embodiments, each chamber may have its own in-situ MW source 302 as illustrated in FIG. 3B.

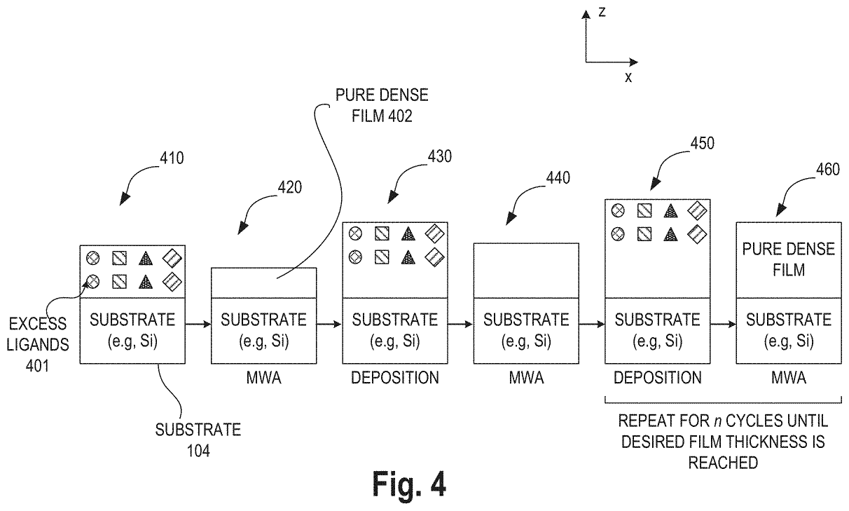

FIG. 4 illustrate an ALD flow 400 with repeated MW annealing (MWA) steps to purify film over substrate, in accordance with some embodiments. After first precursor process 410, excess or unreacted ligands 401 or impurities may remain over substrate 104. After first MWA 420 a pure dense film 402 is formed. Film 402 is free from excess ligands or impurities 401. After second precursor process 430, additional monolayer may be deposited to increase thickness of film 402 along the z-direction. Second precursor process 430 is followed by second MWA 440. After second MWA 440, a pure thicker dense film is formed over substrate 104. The process repeats again as shown by processes 450 and 460.

Performing MWAs in-situ intermittently (every n cycles, with n ranging from at least 1 to as many as 50, depending on growth per cycle) during the ALD process enables even shorter anneal times and lower temperatures than post deposition MWA. The in-situ MWA of various embodiments produce higher quality films with reduced thermal budget and minimal impact to throughput. Because lower temperatures are used, cool down times are reduced, overcoming the big disadvantage of in-situ RTA-enhanced ALD and without the potential detrimental effects of UV exposure. Utilized every n cycles, for a duration ranging from a second to several minutes to tens of minutes, MWAs allow unreacted ligands 401 to diffuse out of the growing film before they effectively become trapped by the overlying deposited material. This yields films of increased purity, drives off residual water, organic impurities, and halides, increased density, and improved electronic properties. The in-situ MWA technique of various embodiments also results in improved properties for ALD thin film diffusion barriers, including improved density, larger grains, and lower impurities.

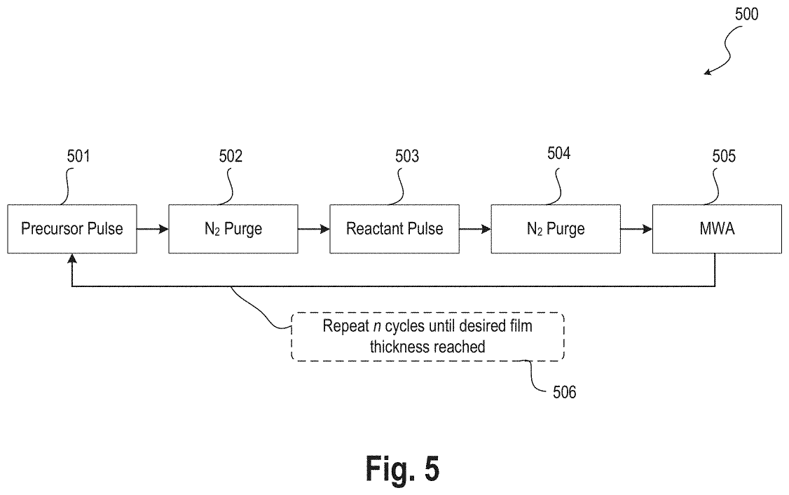

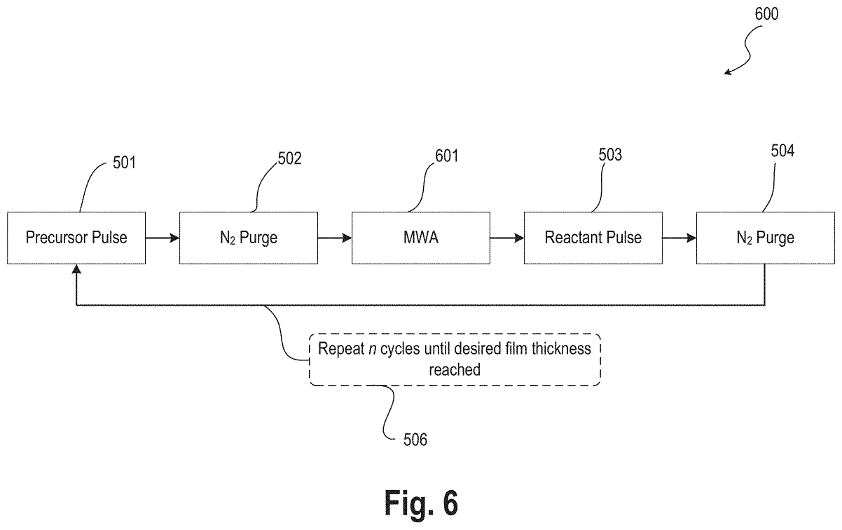

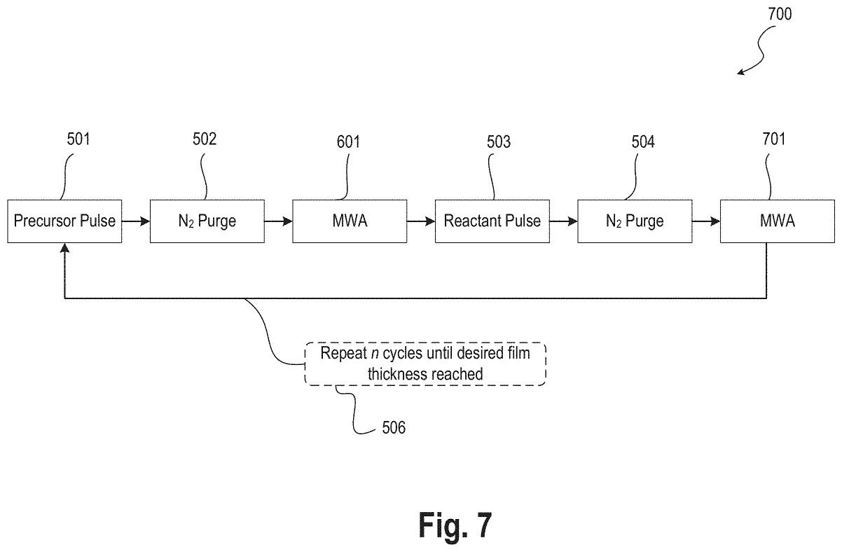

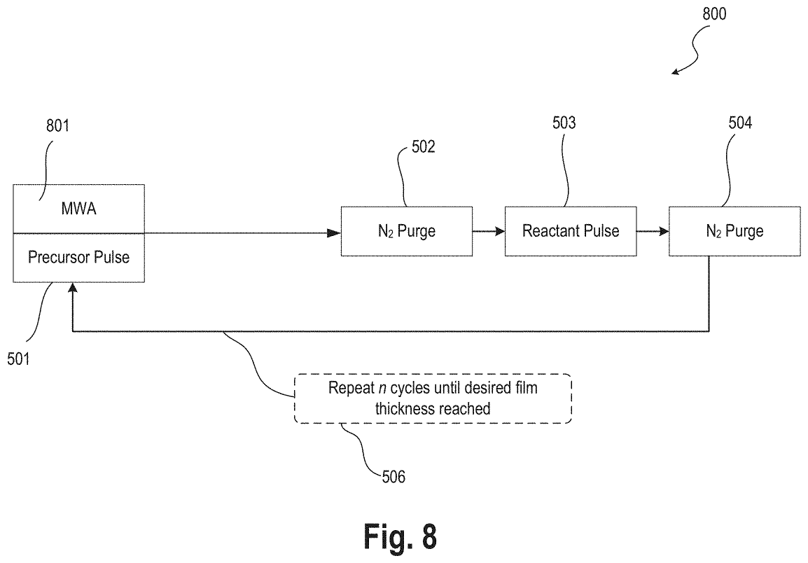

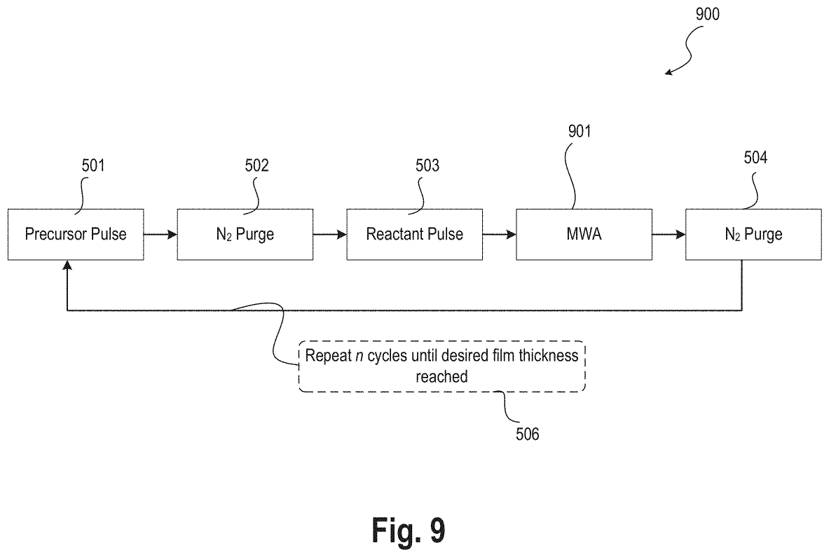

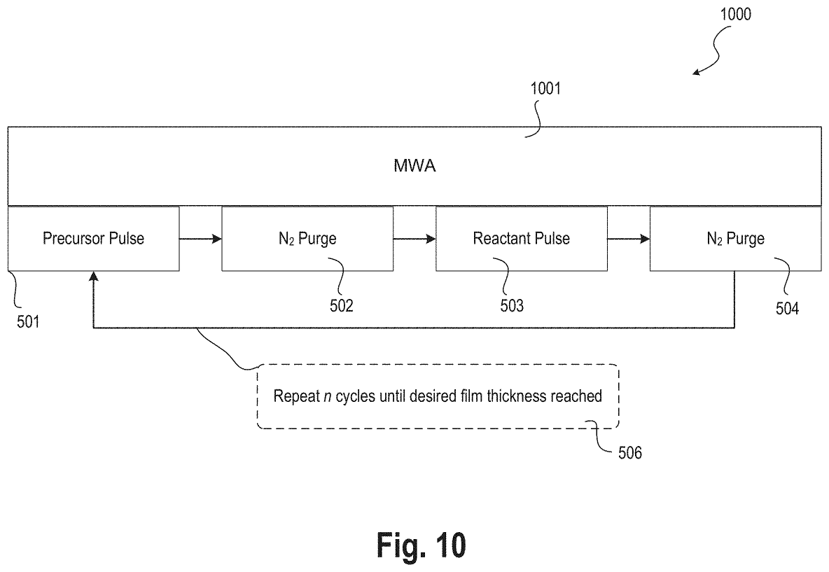

FIGS. 5-10 illustrate ALD flows 500, 600, 700, 800, 900, and 1000, respectively, with different MWA sequences in the ALD process, in accordance with some embodiments. In ALD, individual chemical components are introduced to deposition chamber 101 one at a time. While various ALD flows illustrate MWA performed every cycle, other variations are possible. For example, in some embodiments, MWA is performed every few cycles instead of every cycle while other operations are performed every cycle. These few cycles may be intermittent. For instance, microwave annealing in-situ is performed intermittently.

In ALD flow 500, the process begins with flooding chamber 101 with first precursor that sticks to the exposed surface of substrate 104. This process block 501 is also referred to as the first dose or precursor pulse. Followed by precursor pulse 501, the first precursor dose valve is closed and the precursor lines are purged with N₂ as indicated by process block 502. The purged gas leaves via exhaust line 105. At block 503, a second precursor or reactant pulse is flooded in chamber 101. The second precursor reacts with the first precursor to form a film on substrate 104. At block 504, second precursor dose valve is closed and the second precursor lines are purged with N₂ (Ar or He).

At block 505, MWA is performed in-situ in chamber 101. MW is directly focused on substrate surface 104. In one example, MWA at 915 MHz to 5.8 GHz or higher is applied via MW source 102 for a duration ranging from a second to several minutes to tens of minutes, at power levels of 50-5000 W. MWA allows unreacted ligands to diffuse out of the growing film on substrate 104 before they effectively become trapped by the overlying deposited material. This yields films of increased purity (such as H₂O and carbon), increased density, and improved electronic, optical, and diffusion barrier properties. The process then proceeds to block 501 and the entire process may be repeated n cycles until a desired film thickness is reached as indicated by block 506. Here, ‘n’ can be programmable or fixed number.

In ALD flow 500, MWA is performed after the self-limiting reactant pulse has completed and the excess reactants purged away. No precursor or reactants are in chamber 101 during MWA. Here the substrate or film is expose only after a full self-limiting ALD cycle (layer of material) has been performed (deposited).

In ALD flow 600, compared to flow 500, MWA 601 is performed after the first N₂ purging (block 502). In this example, MWA 505 after the second N₂ purge 504 is not performed. Here, the MWA is performed after the self-limiting precursor pulse has completed and the excess precursor has been purged away. There are no precursor or reactants in chamber during MWA.

In ALD flow 700, compared to flow 600, MWA 701 is performed after the second N₂ purging (block 504) just like in ALD flow 500. In this example, two MWAs 601 and 701 are performed after first N₂ purge 502 and second N₂ purge 504 respectively. Here, MWA takes place after every half cycle has completed and there are no reactants in the chamber during MWA. While this flow may increase benefit over flow 600, but may also take longer time.

In ALD flow 800, compared to flow 500, MWA 801 is performed simultaneously with the first precursor process 501. In this example, MWA 505 after the second N₂ purging (block 504) is not performed. Here, MWA is coincident with the precursor pulse. This might result in addition deposition of greater than a self-limiting monolayer of precursor if the MWA reacts directly with the unreacted physisorbed precursor on the surface or precursor in the gas phase. This may be useful to help boost the reactivity of a precursor with the surface.

In ALD flow 900, compared to flow 500, MWA 901 is performed after second precursor or reactant pulse process 503 and before the second N₂ purging (block 504). In this example, MWA 505 after the second N₂ purge 504 is not performed. Flow 900 may be useful to help boost the reactivity of a reactant with the surface.

In ALD flow 1000, compared to flow 500, MWA 1001 is performed throughout the ALD process and not after any particular process is over. Here, MWA is continuous and will occur while excess precursor and reactant are in the gas phase and physisorbed on the surface and could likely result in CVD and possible plasma formation.

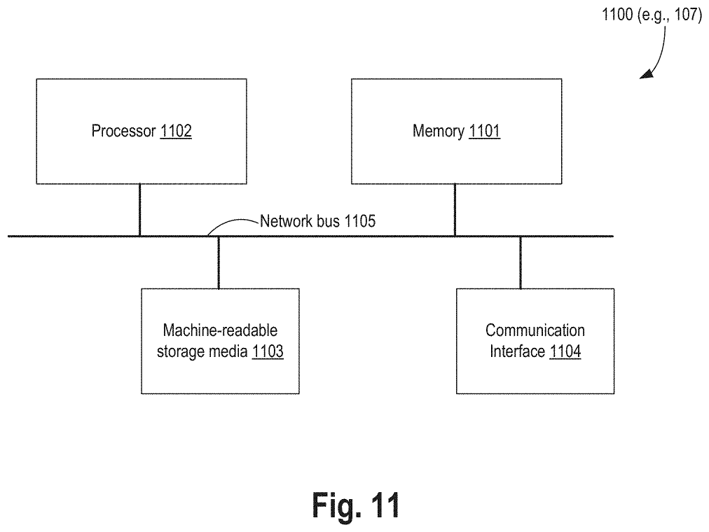

FIG. 11 illustrates computer system 1100 (e.g., 107) which is operable to perform, all or in-part, any one of the schemes described with reference to FIGS. 1-10, in accordance with some embodiments. Elements of embodiments (e.g., flowcharts and scheme described with reference to FIGS. 1-10) are also provided as a machine-readable medium (e.g., memory) for storing the computer-executable instructions or machine-readable instructions (e.g., instructions to implement any other processes discussed herein). In some embodiments, computing platform 1100 comprises memory 1101, processor 1102, machine-readable storage media 1103 (also referred to as tangible machine readable medium), communication interface 1104 (e.g., wireless or wired interface), and network bus 1105 coupled together as shown.

In some embodiments, processor 1102 is a Digital Signal Processor (DSP), an Application Specific Integrated Circuit (ASIC), a general purpose Central Processing Unit (CPU), or a low power logic implementing a simple finite state machine to perform the flowcharts and scheme described with reference to FIGS. 1-10, etc.

In some embodiments, the various logic blocks of system 1100 are coupled together via network bus 1105. Any suitable protocol may be used to implement network bus 1105. In some embodiments, machine-readable storage medium 1101 includes Instructions (also referred to as the program software code/instructions) for optimizing microwave exposure or coupled to wafer (or substrate) as described with reference to various embodiments and flowchart.

Program software code/instructions associated with the flowcharts and scheme described with reference to FIGS. 1-10 and executed to implement embodiments of the disclosed subject matter may be implemented as part of an operating system or a specific application, component, program, object, module, routine, or other sequence of instructions or organization of sequences of instructions referred to as “program software code/instructions,” “operating system program software code/instructions,” “application program software code/instructions,” or simply “software” or firmware embedded in processor. In some embodiments, the program software code/instructions associated the flowcharts and scheme described with reference to FIGS. 1-10 are executed by system 1100.

In some embodiments, the program software code/instructions associated with flowcharts and scheme described with reference to FIGS. 1-10 are stored in a computer executable storage medium 1103 and executed by processor 1102. Here, computer executable storage medium 1103 is a tangible machine readable medium that can be used to store program software code/instructions and data that, when executed by a computing device, causes one or more processors (e.g., processor 1102) to perform a method(s) as may be recited in one or more accompanying claims directed to the disclosed subject matter.

The tangible machine readable medium 1103 may include storage of the executable software program code/instructions (e.g., machine-readable instructions) and data in various tangible locations, including for example ROM, volatile RAM, non-volatile memory and/or cache and/or other tangible memory as referenced in the present application. Portions of this program software code/instructions and/or data may be stored in any one of these storage and memory devices. Further, the program software code/instructions can be obtained from other storage, including, e.g., through centralized servers or peer-to-peer networks and the like, including the Internet. Different portions of the software program code/instructions and data can be obtained at different times and in different communication sessions or in the same communication session.

The software program code/instructions (e.g., flowcharts and scheme described with reference to FIGS. 1-10) and data can be obtained in their entirety prior to the execution of a respective software program or application by the computing device. Alternatively, portions of the software program code/instructions and data can be obtained dynamically, e.g., just in time, when needed for execution. Alternatively, some combination of these ways of obtaining the software program code/instructions and data may occur, e.g., for different applications, components, programs, objects, modules, routines or other sequences of instructions or organization of sequences of instructions, by way of example. Thus, it is not required that the data and instructions be on a tangible machine readable medium in entirety at a particular instance of time.

Examples of tangible computer-readable media 1103 include but are not limited to recordable and non-recordable type media such as volatile and non-volatile memory devices, read only memory (ROM), random access memory (RAM), flash memory devices, floppy and other removable disks, magnetic storage media, optical storage media (e.g., Compact Disk Read-Only Memory (CD ROMS), Digital Versatile Disks (DVDs), etc.), among others. The software program code/instructions may be temporarily stored in digital tangible communication links while implementing electrical, optical, acoustical or other forms of propagating signals, such as carrier waves, infrared signals, digital signals, etc. through such tangible communication links.

In general, tangible machine readable medium 1103 includes any tangible mechanism that provides (i.e., stores and/or transmits in digital form, e.g., data packets) information in a form accessible by a machine (i.e., a computing device), which may be included, e.g., in a communication device, a computing device, a network device, a personal digital assistant, a manufacturing tool, a mobile communication device, whether or not able to download and run applications and subsidized applications from the communication network, such as the Internet, e.g., an iPhone®, Galaxy®, Blackberry® Droid®, or the like, or any other device including a computing device. In one embodiment, processor-based system is in a form of or included within a PDA (personal digital assistant), a cellular phone, a notebook computer, a tablet, a game console, a set top box, an embedded system, a TV (television), a personal desktop computer, etc. Alternatively, the traditional communication applications and subsidized application(s) may be used in some embodiments of the disclosed subject matter.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

Following examples are provided to illustrate the various embodiments. These examples can depend from one another in any suitable manner. For example, example 4 may depend from features of any other examples of the ALD apparatus.

Example 1: An atomic layer deposition (ALD) apparatus comprising: a chamber; a first valve to flood a precursor into the chamber; and a second value to purge the precursor out of the chamber, wherein the chamber comprises: a pedestal to carry a substrate; and a microwave source to direct microwaves on a surface of the substrate.

Example 2: The ALD apparatus of example 1, wherein the microwave source is positioned directly over the pedestal.

Example 3: The ALD apparatus of example 1, wherein the microwave source is a first microwave source, and wherein the chamber comprises a second microwave source to direct microwaves on a surface of the substrate.

Example 4: The ALD apparatus of example 1, wherein the chamber is a first chamber, wherein the ALD apparatus comprises a second chamber coupled to the first chamber via fluid communication.

Example 5: The ALD apparatus of example 1, wherein the microwave source is operable to perform microwave annealing in-situ within the chamber such that the precursor deposited on the substrate is directly exposed to microwave heating without removing the substrate from the chamber.

Example 6: The ALD apparatus of example 1, wherein the microwave source has power in a range from 50 W to 5000 W at a frequency ranging from 915 MHz to 24.125 GHz.

Example 7: The ALD apparatus of example 1, wherein a frequency and power of the microwave source is programmable via a computer communicatively coupled to the chamber.

Example 8: A method for performing atomic layer deposition (ALD), the method comprising: placing a substrate on a pedestal within a chamber; opening a first valve to flood the chamber with a first precursor, wherein the first precursor reacts with a surface of the substrate; closing the first valve and purging the first precursor; opening a second valve to flood the chamber with a second precursor, wherein the second precursor reacts with the first precursor to form a film; closing the second valve and purging the second precursor; and microwave annealing in-situ to purify the film on the substrate.

Example 9: The method of example 8 comprising: repeating n cycles of: opening of the first valve, closing of the first valve, opening of the second valve, closing of the second valve and microwave annealing in-situ to purify the film, to achieve a desired thickness of the film.

Example 10: The method of example 8, wherein microwave annealing in-situ is performed intermittently.

Example 11: The method of example 8, wherein microwave annealing comprises: directing microwave, towards the substrate, with a power in a range from 50 W to 5000 W at a frequency ranging from 915 MHz to 24.125 GHz.

Example 12: The method of example 8 comprising: programming a frequency and power of a microwave source, via a computer communicatively coupled to the chamber, to control the microwave annealing.

Example 13: The method of example 8, wherein purging the first precursor comprises N₂, Ar, or He purging.

Example 14: The method of example 8, wherein purging the second precursor comprises N₂, Ar, or He purging.

Example 15: A machine-readable storage media having machine-readable instructions that, when executed, cause a machine to perform one or more operations including: placing a substrate on a pedestal within a chamber; opening a first valve to flood the chamber with a first precursor, wherein the first precursor reacts with a surface of the substrate; closing the first valve and purging the first precursor; opening a second valve to flood the chamber with a second precursor, wherein the second precursor reacts with the first precursor to form a film; closing the second valve and purging the second precursor; and microwave annealing in-situ to purify the film on the substrate.

Example 16: The machine-readable storage media of example 15 having machine-readable instructions that, when executed, cause a machine to perform one or more operations including: repeating n cycles of: opening of the first valve, closing of the first valve, opening of the second valve, closing of the second valve and microwave annealing in-situ to purify the film, to achieve a desired thickness of the film.

Example 17: The machine-readable storage media of example 15, wherein microwave annealing comprises: directing microwave, towards the substrate, with a power in a range from 50 W to 5000 W at a frequency ranging from 915 MHz to 24.125 GHz.

Example 18: The machine-readable storage media of example 15 having machine-readable instructions that, when executed, cause a machine to perform one or more operations including: adjusting a frequency and power of a microwave source to control the microwave annealing.

Example 19: The machine-readable storage media of example 15, wherein purging the first precursor comprises N₂, Ar, or He purging.

Example 20: The machine-readable storage media of example 15, wherein purging the second precursor comprises N₂, Ar, or He purging.

Example 21: The machine-readable storage media of example 15, wherein microwave annealing is performed during the operations of opening the first valve; closing the first valve and purging the first precursor; opening a second valve; closing the second valve and purging the second precursor.

Example 22: The machine-readable storage media of example 15, wherein microwave annealing in-situ is performed intermittently.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

1-22. (canceled)

23. An atomic layer deposition (ALD) apparatus comprising:
a chamber;
a first valve to flood a precursor into the chamber; and
a second value to purge the precursor out of the chamber, wherein the chamber comprises:
a pedestal to carry a substrate; and
a microwave source to direct microwaves on a surface of the substrate.

24. The ALD apparatus of claim 23, wherein the microwave source is positioned directly over the pedestal.

25. The ALD apparatus of claim 23, wherein the microwave source is a first microwave source, and wherein the chamber comprises a second microwave source to direct microwaves on a surface of the substrate.

26. The ALD apparatus of claim 23, wherein the chamber is a first chamber, wherein the ALD apparatus comprises a second chamber coupled to the first chamber via fluid communication.

27. The ALD apparatus of claim 23, wherein the microwave source is operable to perform microwave annealing in-situ within the chamber such that the precursor deposited on the substrate is directly exposed to microwave heating without removing the substrate from the chamber.

28. The ALD apparatus of claim 23, wherein the microwave source has power in a range from 50 W to 5000 W at a frequency ranging from 915 MHz to 24.125 GHz.

29. The ALD apparatus of claim 23, wherein a frequency and power of the microwave source is programmable via a computer communicatively coupled to the chamber.

30. A method for performing atomic layer deposition (ALD), the method comprising:
placing a substrate on a pedestal within a chamber;
opening a first valve to flood the chamber with a first precursor, wherein the first precursor reacts with a surface of the substrate;
closing the first valve and purging the first precursor;
opening a second valve to flood the chamber with a second precursor, wherein the second precursor reacts with the first precursor to form a film;
closing the second valve and purging the second precursor; and
microwave annealing in-situ to purify the film on the substrate.

31. The method of claim 30 comprising:
repeating n cycles of: opening of the first valve, closing of the first valve, opening of the second valve, closing of the second valve and microwave annealing in-situ to purify the film, to achieve a desired thickness of the film.

32. The method of claim 30, wherein the microwave annealing in-situ is performed intermittently compared to opening of the first valve, closing of the first valve, opening of the second valve, and closing of the second valve.

33. The method of claim 30, wherein the microwave annealing comprises:
directing microwave, towards the substrate, with a power in a range from 50 W to 5000 W at a frequency ranging from 915 MHz to 24.125 GHz.

34. The method of claim 30 comprising:
programming a frequency and power of a microwave source, via a computer communicatively coupled to the chamber, to control the microwave annealing.

35. The method of claim 30, wherein purging the first precursor comprises N₂, Ar, or He purging.

36. The method of claim 30, wherein purging the second precursor comprises N₂, Ar, or He purging.

37. A machine-readable storage media having machine-readable instructions that, when executed, cause a machine to perform one or more operations including:
placing a substrate on a pedestal within a chamber;
opening a first valve to flood the chamber with a first precursor, wherein the first precursor reacts with a surface of the substrate;
closing the first valve and purging the first precursor;
opening a second valve to flood the chamber with a second precursor, wherein the second precursor reacts with the first precursor to form a film;
closing the second valve and purging the second precursor; and
microwave annealing in-situ to purify the film on the substrate.

38. The machine-readable storage media of claim 37 having machine-readable instructions that, when executed, cause a machine to perform one or more operations including:
repeating n cycles of: opening of the first valve, closing of the first valve, opening of the second valve, closing of the second valve and microwave annealing in-situ to purify the film, to achieve a desired thickness of the film.

39. The machine-readable storage media of claim 37, wherein the microwave annealing comprises:
directing microwave, towards the substrate, with a power in a range from 50 W to 5000 W at a frequency ranging from 915 MHz to 24.125 GHz.

40. The machine-readable storage media of claim 37 having machine-readable instructions that, when executed, cause a machine to perform one or more operations including:
adjusting a frequency and power of a microwave source to control the microwave annealing.

41. The machine-readable storage media of claim 37, wherein purging the first precursor comprises N₂, Ar, or He purging.

42. The machine-readable storage media of claim 37, wherein:
purging the second precursor comprises N₂, Ar, or He purging; and
the microwave annealing is performed during the operations of opening the first valve; closing the first valve and purging the first precursor; opening a second valve;
closing the second valve and purging the second precursor; or
the microwave annealing in-situ is performed intermittently.
